(19) United States
(12) Patent Application Publication
(10) Pub. No.: US 2024/0288525 A1
(43) Pub. Date: Aug. 29, 2024

(54) Computer-Implemented Operation of a Magnetic Resonance Facility

(71) Applicant: Siemens Healthineers AG, Forchheim (DE)

(72) Inventors: Mario Zeller, Erlangen (DE); Andreas Krug, Fürth (DE)

(73) Assignee: Siemens Healthineers AG, Forchheim (DE)

(21) Appl. No.: 18/583,962

(22) Filed: Feb. 22, 2024

(30) Foreign Application Priority Data
Feb. 23, 2023 (EP) 23158173.7

(51) Int. Cl. G01R 33/56; G06T 7/00

(52) U.S. Cl. CPC G01R 33/5608; G06T 7/0012; G06T 2207/10088; G06T 2207/20081; G06T 2207/20084

(57) ABSTRACT

A computer-implemented method for operating a magnetic resonance facility to determine at least one potential cause for a false value in the image data of at least one imaging procedure, compiling an input dataset that is to be analyzed and comprises radiofrequency signal data acquired during the imaging procedure, applying a trained artificial intelligence classification function to the input dataset to determine an output dataset that describes the potential causes of the false value, and outputting at least a portion of the output data of the output dataset.

### BACKGROUND

Independent of the grammatical term usage, individuals with male, female, or other gender identities are included within the term.

The disclosure relates to a computer-implemented method for operating a magnetic resonance facility, wherein at least one potential cause of a false value, in particular a spike false value, is identified in the image data of at least one imaging procedure. The disclosure additionally relates to a computer program, an electronically readable data medium, and a computing facility, in particular, a control facility of a magnetic resonance facility.

Magnetic resonance imaging is a well-established imaging modality, particularly in the field of medicine. It provides high-precision views into objects that are to be examined, in particular the human body. A main magnetic field (B0 field) is generated by means of a main magnet of a main magnet unit positioned in a shielded cabin of a magnetic resonance facility, wherein by using at least one radiofrequency coil array to generate excitation pulses, it is possible to excite nuclear spins in the object that is to be examined. The decay of these excitations is measured as magnetic resonance signals. Gradient fields generated by means of a gradient coil array are used for spatial encoding. In the process, the magnetic resonance data is typically measured in the spatial frequency domain known as the k-space and is transformed into the image space.

Magnetic resonance imaging is also subject to measurement errors, i.e., incorrect values (false values) in image data acquired during an imaging procedure due to a variety of causes. Specifically needing to be mentioned in this context are errors referred to as spike false values, i.e., signals measured incorrectly at too high an intensity in the k-space. Spike false values may, therefore, be understood as k-space values, i.e., measurement values of the image data, which describe no real property of an examined object and are, in particular, peaks/intensity peaks. Such false values can cause different artifacts or effects in the reconstructed magnetic resonance dataset generally, in particular in the reconstructed image, for example, a reduced signal-to-noise ratio, shading, or other image artifacts. Examples of causes for spike false values include voltage surges, vibrating mechanical parts, foreign bodies such as, for example, coins in the patient receiving chamber, or external radiofrequency interference effects. External radiofrequency interference effects can be produced, for example, by power supply units in the shielded cabin, defective fluorescent tubes, and/or effects from outside due to an incorrectly closed door to the shielded cabin.

In a real-world example, spike false values that pass through the normal image reconstruction process such as filtering, Fourier transformation, and further operations, for example, reconstruction algorithms in parallel imaging, and that are triggered by vibrating parts in the patient couch can cause strong diagonal stripes in the resulting image which, in the event that they overlap relevant image information, can lead to poorer identifiability of the latter and/or can be mistakenly evaluated as relevant image information.

Various approaches for detecting and removing spike false values have already been proposed in the prior art. In particular, hardware-based filters and software-based approaches exist in this regard.

DE 10 2018 216 362 B3 discloses a method and a system for cleaning a magnetic resonance measurement dataset. In the method, a measurement dataset consisting of k-space values is acquired, after which one or more GRAPPA kernels are calibrated for the or on the measurement dataset. The k-space values of the measurement dataset are then verified against a predefined intensity criterion in order to identify false values. The k-space values of the measurement dataset are then reconstructed point by point by means of the calibrated GRAPPA kernels by a respective linear combination of respective other k-space values, which are selected according to a predefined schema. The false values are replaced by the corresponding reconstructed k-space values in order to generate a cleaned measurement dataset. A check to verify whether a predefined threshold value has been exceeded can be conducted in the intensity criterion, for example.

U.S. Pat. No. 10,705,170 B1 relates to methods and systems for removing spike noise in magnetic resonance imaging. In this method, it is proposed that a trained deep-learning network be used in order to identify and correct spike noise, in particular, to reduce or remove said spike noise. In particular, it should be possible in this process to distinguish spikes close to the k-space center from strong, correct magnetic resonance signals.

As has already been explained, spike false values may be attributable to different causes, the elimination of which entails different degrees of complexity (closing doors, replacing fluorescent tubes, picking up and removing coins, swapping gradient coils, and the like). If a message reporting trouble is issued, a technician is usually dispatched to the magnetic resonance facility in order to identify the cause. This is disadvantageous both with regard to the costs and with regard to the other overheads. Furthermore, there is the risk that the actual cause will be overlooked.

### SUMMARY

An object underlying the disclosure is, therefore, to disclose an easier troubleshooting approach when spike false values occur in image data during imaging procedures.

This object is achieved according to the disclosure by means of a computer-implemented method, a computer program, an electronically readable data medium, and a computing facility according to the independent claims. Advantageous embodiments will become apparent from the dependent claims.

In order to determine at least one potential cause for a false value, in particular a spike false value, in the image data of at least one imaging procedure, a computer-implemented method according to the disclosure for operating a magnetic resonance facility comprises the following steps:
compiling an input dataset that is to be analyzed and comprises radiofrequency signal data acquired during the imaging procedure,
applying a trained artificial intelligence classification function to the input dataset in order to determine an output dataset describing the potential causes of the false value, and
outputting at least a portion of the output data of the output dataset.

It has been recognized, according to the disclosure, that the causes of spike false values can often be attributed to a particular pattern in radiofrequency signal data (as well as possibly further data), wherein the radiofrequency signal data may particularly advantageously include at least a portion of the image data of the imaging procedure in the k-space and/or in a hybrid space and/or in the image space. It has been observed, for example, that spike false values occur due to defective fluorescent tubes at a plurality of positions in the ky-direction, but in each case at the same kx position in the k-space. Loosely attached gradient cables of the gradient coils cause spike false values usually at the beginning or at the end of the k-space in the kx-direction. Still, they are more randomly distributed in the ky-direction. Metal parts in the, in particular cylindrical, patient receiving chamber of a main magnet unit of the magnetic resonance facility lead to completely random distributions. Further differences in the various causes can result, for example, from whether the spike false values occur as a function of high currents or voltages. As a result of these findings, it is proposed to use a trained artificial intelligence classification algorithm, in particular comprising a neural network, for classifying the cause of the false value on the basis of input data acquired during the imaging procedure that includes at least radiofrequency signal data.

In general, a trained function, i.e., also the trained classification function, maps cognitive functions that human beings associate with other human brains. By means of training based on training data (machine learning), the trained function can adapt to new circumstances and detect and extrapolate patterns.

Generally speaking, parameters of a trained function can be adapted by means of training. In particular, supervised learning, semi-supervised learning, unsupervised learning, reinforcement learning, and/or active learning can be used. In addition, representation learning (also known as “feature learning”) can also be used. In particular, the parameters of the trained function can be adapted iteratively by means of multiple training steps.

A trained function may, for example, comprise a neural network, a support vector machine (SVM), a decision tree, and/or a Bayesian network, and/or the trained function may be based on k-means clustering, Q-learning, genetic algorithms, and/or association rules. In particular, a neural network may be a deep neural network, a convolutional neural network (CNN), or a deep CNN. In addition, the neural network may be an adversarial network, a deep adversarial network, and/or a generative adversarial network (GAN).

The trained classification function may also be embodied for detecting the presence of at least one false value and for outputting an output dataset indicating the presence of no false value if no false value is detected. Alternatively, the presence of a false value may be established in advance in some other way, in particular by means of a corresponding, possibly likewise trained, detection function, in which case the trained classification function is then used for further analysis only if the detection function returns a positive result.

False values, in particular spike false values, within the meaning of the disclosure are k-space values, i.e., measurement values of the image data, which have actually or presumably been generated, modified, or affected by sources of interference and therefore indicate or describe no actual property of a respective examined object. False values may, therefore, be understood as contaminations of the measurement dataset containing the image data. In particular, the false values, in particular spike false values, can be peaks and/or intensity peaks, i.e., excessive signal energies in the k-space, which, during a reconstruction of a magnetic resonance image, or generally of a magnetic resonance dataset, from the k-space values can lead and/or contribute to image interferences and/or artifacts.

If, as is preferred, image data of the at least one imaging procedure is used as radiofrequency signal data, this data can be present for example in the form of a matrix filled with the k-space values. In this case, the rows of such a matrix often lie in the kx-direction and may be understood as k-space lines. The k-space representation of the image data offers the advantage that spike false values are usually present as clearly definable points. For classification purposes, however, an image space representation of the image data or a hybrid space representation in which, for example, a Fourier transform has been only partially performed may also be beneficial. Individual points in the k-space lead to wave patterns in the image space, which can be particularly effectively detected by trained classification function architectures trained in pattern recognition, in particular when the spike false values are located close to the signal-rich k-space center.

In a first step of the method according to the disclosure, an input dataset is compiled containing input data for the trained classification algorithm. The basis for this compilation may be procedure data of the at least one imaging procedure received via a first interface.

As already mentioned, the radiofrequency signal data preferably comprises at least a portion of the image data of the imaging procedure in the k-space and/or in a hybrid space and/or in the image space. It is particularly advantageous in this case if, during the acquisition of multiple k-space sections following a common excitation pulse in one shot, the k-space sections are assigned, in particular with respect to time, to the respective shot as an additional dimension of the radiofrequency signal data of the input dataset. In this case, k-space sections can correspond in particular to k-space lines. Magnetic resonance sequences in which multiple k-space lines are acquired, comprising, for example, what are termed TSE sequences (TSE=Turbo Spin-Echo), in “shots,” which use a common excitation pulse triggered at different time instants. Furthermore, in other acquisition techniques, k-space sections may also be k-space segments, diffusion repetitions, and the like. With such k-space sections acquired at different time intervals, it can be beneficial to combine, in other words to concatenate, the radiofrequency signal data in an additional dimension, thereby particularly advantageously making it easier for the trained classification algorithm to recognize temporal correlations. Similarly, beneficial exemplary embodiments of the disclosure can provide, as a further dimension of the radiofrequency signal data of the input dataset, the use of an assignment to a coil channel in which the data was acquired. Retaining coil channels as a further dimension can disclose the spatial origin of false values and enable the trained classification algorithm generally to take into account spatial correlations.

In an embodiment of the present disclosure, it is furthermore also possible, in particular in addition to image data as radiofrequency signal data, for the radiofrequency signal data to include sensor data acquired by at least one further radiofrequency sensor of the magnetic resonance facility that is not used for imaging. Such further radiofrequency sensors may comprise, for example, pickup coils and/or a breath sensor. Providing radiofrequency sensors, in particular pickup coils, at various points in the radiofrequency shielded cabin has already been proposed in a different context as a means of detecting different interference effects. For example, it can be provided that pickup coils of said type are disposed in the patient receiving chamber, for example, at the edge of the patient receiving chamber, specifically on the cladding, and/or on the patient table, and/or in or on an electronics component, in particular a transmit and/or receive electronics component, and/or outside the patient receiving chamber in the radiofrequency shielded cabin. In this case, a spatial distribution of radiofrequency signals is also described, which provides a pointer indicating the causes of false values in the image data of at least one imaging procedure. This also applies to different types of breath sensors, in particular such that use a coil- and/or capacitor-like arrangement in order to detect differences in the dielectric configuration of the human body in different respiratory states. Radiofrequency signals can also be received by means of such breath sensors, so these can provide useful information for the input dataset.

In addition to the radio frequency signal data, the input dataset may also comprise at least one item of supplementary information about the imaging procedure. Such supplementary information can significantly improve the classification performance and/or support further detection and/or classification results, i.e., extensions of the output dataset.

Specifically, it can be provided, for example, that the supplementary information is chosen from the group comprising
coil information describing coils used for imaging,
orientation information describing an orientation of measured volumes, in particular layers,
gradient information describing gradient pulses, in particular of a main gradient direction, played out during the imaging procedure,
at least one temperature measurement value of a temperature sensor of the magnetic resonance facility, and
a door sensor signal indicating the closure state of a door of a shielded cabin of the magnetic resonance facility.

Whereas a door signal indicating an open door to the radiofrequency shielded cabin can provide an alert pointing to causes originating outside the RF shielded cabin, other causes occur only in certain temperature ranges, so temperature information, specifically at least one temperature measurement value, likewise represents useful supplementary information.

Providing coil information, orientation information, and gradient information is particularly advantageous, however. While it may already be conceivable for the trained classification function in principle, for example, on account of coil channel assignments, to ascertain, in relation to at least one cause, localization information describing the location of the cause and to add this to the output dataset, supplementary information offers extended possibilities in this case. In particular, therefore, it can be provided that the trained classification function, by using the supplementary information, in particular the coil information and/or the orientation information and/or the gradient information, determines, in relation to at least one cause, localization information describing the location of the cause. For example, a defective cable and/or a defective coil winding can be identified if it is known where and/or how the coils are used and/or which main gradient activity is present, for example, in the case of diffusion measurements. This constitutes important and extremely useful supplementary information, in particular for a user as well as for a repair technician.

A vector (array) of probability values can particularly advantageously be output as an output dataset. In this case, each entry in the vector is assigned a cause, for example, a type of interference. Every entry in the vector may, in this case, also be understood as a “channel” that is assigned to a cause and contains a respective probability for the cause. From probabilities of the type, it is also possible to determine a unique classification, i.e., a specific cause, at least when a uniqueness criterion is fulfilled. This is beneficial, for example, when the probability for a specific cause is higher, in particular significantly so than the probabilities for all other causes or even the sum total thereof. In this context, it is conceivable that a vector position, in particular the first (or zero) vector position, is assigned to no recognized cause or, if the trained classification function is also embodied for detecting the presence of a false value, no recognized sources of interference. In particular, the output dataset, for example, when localization information is determined as part of an entry in the vector and/or assigned to a vector position, may also include further contents, for example, the localization information. It is, of course, also conceivable to provide separate entries in the vector for each localization. Generally, possible assignments comprise, for example, “loose gradient cable,” “voltage surge in gradient coil,” “radiofrequency interference sources outside the shielded cabin,” “radiofrequency interference sources inside the shielded cabin,” “object in the patient receiving chamber,” and the like.

In an advantageous embodiment of the present disclosure, the trained function may comprise a ResNet, in particular a ResNet-18, and/or an AlexNet and/or a SqueezeNet, as a neural network. All these neural networks are CNNs, which are particularly suitable for classification tasks, in particular from image data, which is, of course, preferably included in the input data. Generally, it can be said that CNNs have a convolutional base for generating features from the input data, in particular image data, which may, in particular, comprise convolutional layers and pooling layers. The convolutional base is then usually followed by a classifier, which may contain one or more fully connected layers. The main purpose of the classifier is the classification of the input data based on the features extracted by means of the convolutional base. In other words, a feature extraction in the convolutional base is followed by a classification in the classifier in order to provide the output data of the output dataset. A ResNet, short for “Residual Neural Network,” is characterized in that deeper neural networks can be created by using what is called “skip connections” or “shortcuts” in order to bypass layers. The numbers used to designate ResNets, i.e., for example, 18, 34, and the like, denote layers, although the architecture is the same. Two main types of blocks exist in a ResNet, namely identity blocks when the input and output activation dimensions are the same and convolutional blocks when the input and output activation dimensions are different. For example, in order to reduce the activation dimensions by a factor of 2, use can be made of a 1×1 convolution with a “stride” of two. For example, ResNet-18 comprises multiple convolutional blocks in the convolutional base, followed by the classifier. Furthermore, for further information on ResNets, reference should be made also to the seminal article by K. He et al., “Deep residual learning for image recognition” (arXiv preprint arXiv:1512.03385, 2015). In this regard, the particularly preferred ResNet-18 has the advantage of providing a good compromise between accuracy and speed.

In an advantageous development of the disclosure, it can be provided that at least one measure is determined and actioned on the basis of the outputted output data. A measure can, therefore, be derived based on the result of the regression/classification. In this respect, the output of at least a portion of the output data of the output dataset may be understood in this case as a forwarding to a measures unit. The at least one measure can be chosen from the group comprising
storing an entry in an error memory,
outputting an alert, in particular, relating to the outputted output data and/or containing said output data, to a user,
sending a message, in particular relating to the outputted output data and/or containing said output data, to a maintenance service, and
applying a correction algorithm, in particular, chosen on the basis of the outputted output data and/or using said output data, to the image data.

In addition to often beneficial entries into an error memory, a message to a remote service monitoring point, in particular within the scope of a predictive maintenance strategy, or the output of a warning to operating personnel is extremely beneficial. A message to a maintenance service can, for example, include an alert indicating that cables and/or gradient coils and/or radiofrequency amplifiers and/or other components need to be checked. The output of a warning to operating personnel can, for example, declare “Interfering signals detected. Please check whether the door to the scanner room is closed.”, “Interfering signals detected. Please check whether power supply units, defective fluorescent tubes, etc., are present in the scanner room.”, “Interfering signals detected. Please check whether metal parts are present in the patient receiving chamber.”, or similar.

The classification of the cause of the false value can also be used to select a suitable error correction measure. For example, a suitable correction algorithm can be selected, in particular a neural network for removing random sources of interference and/or other correction algorithms, for example, a truncation of the first two data points of each k-space line and the like. The removal of the source of interference can, therefore, be chosen in an optimal targeted manner according to its cause, and as a result, the correction of the image effects occurring due to the false value can also be improved.

In order to provide the trained classification function, the classification function is trained using suitable training datasets. Also conceivable in principle in this case is an autonomous provisioning method for providing the trained classification function, which method comprises the providing of the classification function that is to be trained and training datasets via a first training interface, a training of the classification function on the basis of the training datasets by means of a processor, as well as a providing of the trained classification information via a second training interface. In this case, the classification function is trained in particular on the basis of annotated input datasets, to which a ground truth is therefore assigned. Since spike false values generally occur in large numbers, a great deal of affected image data is typically present in the event of an error. Nevertheless, it can represent a challenge to obtain a great number of suitable datasets for different causes.

A particularly advantageous development of the present disclosure, therefore, provides that a pretrained classification function is made available in order to provide the trained classification function and is trained by means of transfer learning on the basis of training datasets, each training dataset comprising an input dataset and an associated ground truth. The associated ground truth may already be formulated as the corresponding output dataset. It is therefore proposed to adapt a pretrained model, for example, ResNet-18, by means of transfer learning in order to keep the number of required training datasets within reasonable limits.

CNNs are mostly provided as pretrained functions, in which case, as already explained, a classification function comprising a ResNet, in particular a ResNet-18, can particularly advantageously be used within the scope of the present disclosure.

Furthermore, it may be beneficial within the scope of the training if at least some of the input datasets of the training datasets are determined from base datasets free of false values by means of characteristics information assigned to causes. It is, therefore, possible to synthesize training datasets when the characteristics of the causes can be effectively simulated. For example, it can be provided to synthesize a plurality of input datasets containing different spike causes from an input dataset of spike-free input data. An additional training base can be created in this way.

Overall and in summary, it can therefore be said that as a result of the proposed classification according to the disclosure of the cause of interference effects, in particular of spike false values, it is possible to achieve a reduction in technician callouts, an expansion of predictive maintenance and a swifter problem resolution by the users themselves in the sense of an “aid to self-help.”

A computer program, according to the disclosure, can be loaded directly into a memory of a computing facility, in particular of a control facility of a magnetic resonance facility, and has program means such that when the computer program is executed on the computing facility, the latter performs the steps of a method according to the disclosure. The computer program can be stored on an electronically readable data medium according to the disclosure such that when the data medium is used in a computing facility, in particular a control facility of a magnetic resonance facility, the control facility is embodied to perform a method according to the disclosure. The electronically readable data medium, according to the disclosure, is, in this case, in particular, a non-transitory data medium. A corresponding training computer program and a corresponding training data medium are also analogously conceivable for the conceivable training method.

Finally, the disclosure also relates to a computing facility, in particular, a control facility of a magnetic resonance facility, which, in order to determine at least one potential cause for a false value, in particular a spike false value, in the image data of at least one imaging procedure, comprises:
a first interface for receiving procedure data describing the imaging procedure and comprising at least radiofrequency signal data acquired during the imaging procedure,
a compilation unit for compiling, from the procedure data, an input dataset that is to be analyzed and contains the at least one portion of the radiofrequency signal data,
a classification unit for applying a trained artificial intelligence classification function to the input dataset in order to determine an output dataset that describes potential causes of the false value, and
a second interface for outputting at least a portion of the output data of the output dataset.

All statements made in relation to the method according to the disclosure can be applied analogously to the computing facility, the computer program, and the electronically readable data medium according to the disclosure, such that the already cited advantages can also be obtained with these.

The computing facility, according to the disclosure, preferably has at least one processor and at least one storage means. The cited functional units can be formed at least in part by means of hardware and/or at least in part by means of software, in particular using program means of the computer program according to the disclosure. In addition to the cited functional units, i.e., compilation unit and classification unit, the computing facility may, of course, also comprise further functional units for realizing further steps of the method according to the disclosure, for example, a measures unit and, where appropriate, even a training unit. A separate training system for performing the conceivable provisioning method for the trained classification function is also conceivable. Beneficially, the computing facility is a control facility of a magnetic resonance facility. In this case, a check on imaging procedures can take place directly at the magnetic resonance facility, and if radiofrequency interferences, in particular spike false values, occur, a classification of the causes can be carried out directly on site. For example, this enables alerts to be output to users already directly at the magnetic resonance facility and/or suitable correction measures to be selected immediately or correction measures to be adapted.

### BRIEF DESCRIPTION OF THE DRAWINGS

Further advantages and details of the present disclosure will become apparent from the exemplary embodiments described in the following, as well as with reference to the drawings, in which:

FIG. 1 shows an exemplary embodiment of an artificial neural network,

FIG. 2 shows an exemplary embodiment of a convolutional neural network,

FIG. 3 shows a flowchart of an exemplary embodiment of the method according to the disclosure,

FIG. 4 shows an explanatory illustration relating to the preparation of input data,

FIG. 5 schematically shows the structure of a trained classification function used,

FIG. 6 shows steps for training the trained classification function,

FIG. 7 shows the functional structure of a computing facility according to the disclosure, and

FIG. 8 shows a magnetic resonance facility.

### DETAILED DESCRIPTION

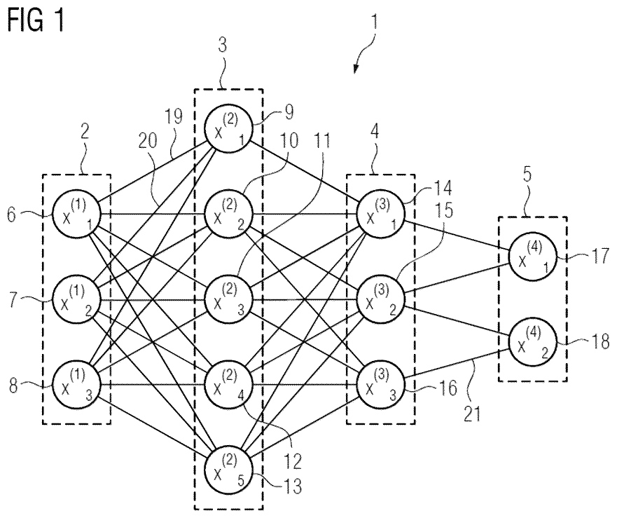

FIG. 1 shows an exemplary embodiment of an artificial neural network 1. Alternative terms for the artificial neural network 1 are “neural network,” “artificial neural net,” or “neural net.”

The artificial neural network 1 comprises nodes 6 to 18 and edges 19 to 21, where each edge 19 to 21 is a directed connection from a first node 6 to 18 to a second node 6 to 18. Generally, the first node 6 to 18 and the second node 6 to 18 are different nodes 6 to 18, though it is also conceivable that the first node 6 to 18 and the second node 6 to 18 are identical. In FIG. 1, for example, edge 19 is a directed connection from node 6 to node 9 and edge 21 is a directed connection from node 16 to node 18. An edge 19 to 21 from a first node 6 to 18 to a second node 6 to 18 is referred to as an ingoing edge (or “inbound edge”) for the second node 6 to 18 and as an outgoing edge (or “outbound edge”) for the first node 6 to 18.

In this exemplary embodiment, nodes 6 to 18 of the artificial neural network 1 can be arranged in layers 2 to 5, where the layers can have an intrinsic order, which is introduced by edges 19 to 21 between nodes 6 to 18. In particular, edges 19 to 21 can be provided only between neighboring layers of nodes 6 to 18. In the exemplary embodiment shown, there exists an input layer 2 which comprises only nodes 6, 7, 8, in each case without ingoing edge. The output layer 5 comprises only nodes 17, 18, in each case without outgoing edges, with additional hidden layers 3 and 4 being located between input layer 2 and output layer 5. In the general case, the number of hidden layers 3, 4 can be chosen arbitrarily. The number of nodes 6, 7, 8 in input layer 2 typically corresponds to the number of input values into neural network 1, and the number of nodes 17, 18 in output layer 5 typically corresponds to the number of output values of the neural network 1.

In particular, nodes 6 to 18 of neural network 1 can be assigned a (real) number. In this case, x⁽ⁿ⁾ᵢ denotes the value of the i-th node 6 to 18 of the n-th layer 2 to 5. The values of nodes 6, 7, 8 of input layer 2 are equivalent to the input values of neural network 1, whereas the values of nodes 17, 18 of output layer 5 are equivalent to the output values of neural network 1. In addition, each edge 19, 20, 21 can be assigned a weight in the form of a real number. The weight is, in particular, a real number in the interval [−1, 1] or in the interval [0, 1,]. In this case w^{(m,n)}_{i,j} denotes the weight of the edge between the i-th node 6 to 18 of the m-th layer 2 to 5 and the j-th node 6 to 18 of the n-th layer 2 to 5. Furthermore, the abbreviation w is defined for the weight w_{i,j}^{(m,n+1)}.

In order to calculate output values of neural network 1, the input values are propagated through neural network 1. In particular, the values of nodes 6 to 18 of the (n+1)-th layer 2 to 5 are calculated based on the values of nodes 6 to 18 of the n-th layer 2 to 5 by

$${x}_{j}^{( n + 1 )} = f ( {\sum }_{i} {x}_{i}^{( n )} \cdot {w}_{i , j}^{( n )} ) .$$

In this case, f is a transfer function, which may also be referred to as an activation function. Known transfer functions are step functions, sigmoid functions (for example, the logistic function, the generalized logistic function, the hyperbolic tangent, the arcus tangent, the error function, the smoothstep function), or rectifier functions. The transfer function is essentially used for normalization purposes.

In particular, the values are propagated layer by layer through the neural network 1, values of input layer 2 being given by the input data of neural network 1. Values of the first hidden layer 3 can be calculated based on the values of input layer 2 of the neural network 1, while values of the second hidden layer 4 can be calculated based on the values in the first hidden layer 3, etc.

In order to be able to specify values w_{i,j}⁽ⁿ⁾ for edges 19 to 21, neural network 1 must be trained using training data. Training data comprises, in particular, training input data and training output data, designated in the following as tᵢ. For a training step, neural network 1 is applied to the training input data in order to determine calculated output data. In particular, the training output data and the calculated output data comprise a number of values, the number being determined as the number of nodes 17, 18 in the output layer 5.

In particular, a comparison between the calculated output data and the training output data is used in order to recursively adjust the weights within neural network 1 (backpropagation algorithm). In particular, the weights can be varied according to

$${w}_{i , j}^{′ ( n )} = {w}_{i , j}^{( n )} - γ \cdot {δ}_{j}^{( n )} \cdot {x}_{i}^{( n )} ,$$

where γ is a learning rate and the numbers δⱼ⁽ⁿ⁾ can be calculated recursively as

$${δ}_{j}^{( n )} = ( {\sum }_{k} {δ}_{k}^{( n + 1 )} \cdot {w}_{j , k}^{( n + 1 )} ) \cdot {f}^{′} ( {\sum }_{i} {x}_{i}^{( n )} \cdot {w}_{i , j}^{( n )} )$$

based on δⱼ⁽ⁿ⁺¹⁾ if the (n+1)-th layer is not output layer 5, and

$${δ}_{j}^{( n )} = ( {x}_{k}^{( n + 1 )} - {t}_{j}^{( n + 1 )} ) \cdot {f}^{′} ( {\sum }_{i} {x}_{i}^{( n )} \cdot {w}_{i , j}^{( n )} )$$

if the (n+1)-th layer is output layer 5, where f′ is the first derivative of the activation function and yⱼ⁽ⁿ⁺¹⁾ is the comparison training value for the j-th node 17, 18 of the output layer 5.

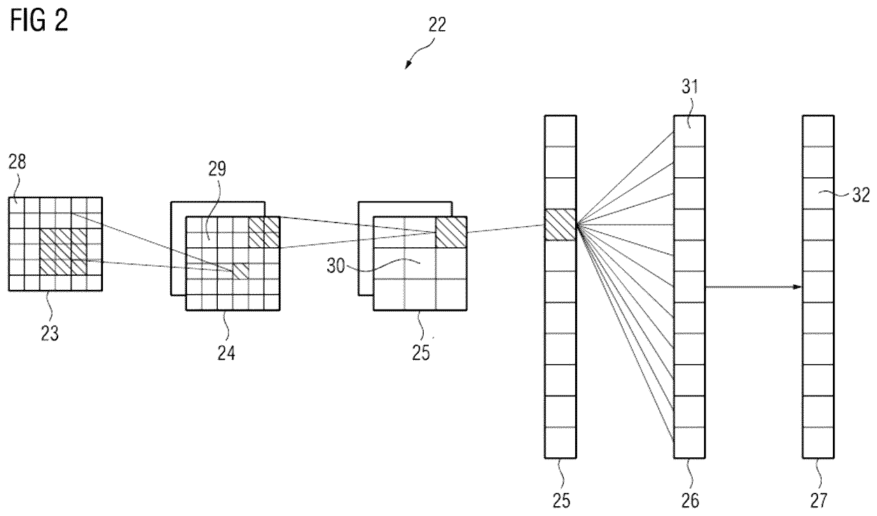

An example of a convolutional neural network (CNN) is also given below with regard to FIG. 2. It should be noted in this case that the term “layer” is employed there in a slightly different way from that in the case of classical neural networks. For a classical neural network, the term “layer” refers only to the set of nodes forming a layer, i.e., a specific generation of nodes. For a convolutional neural network, the term “layer” is often used as an object that actively modifies data, in other words, as a set of nodes of the same generation and either the set of ingoing or outgoing edges.

FIG. 2 shows an exemplary embodiment of a convolutional neural network 22. In the exemplary embodiment shown, the convolutional neural network 22 comprises an input layer 23, a convolutional layer 24, a pooling layer 25, a fully connected layer 26, and an output layer 27. In alternative embodiments, convolutional neural network 22 can contain multiple convolutional layers 24, multiple pooling layers 25 and multiple fully connected layers 26, just like other types of layers. The order of the layers can be chosen arbitrarily, fully connected layers 26 typically forming the last layers before output layer 27.

In particular, the nodes 28 to 32 of one of the layers 23 to 27 within a convolutional neural network 22 may be understood as arranged in a d-dimensional matrix or as a d-dimensional image. In particular, in the two-dimensional case, the value of a node 28 to 32 having the indices i, j in the n-th layer 23 to 27 can be designated as x⁽ⁿ⁾[i,j]. It should be pointed out that the arrangement of nodes 28 to 31 in a layer 23 to 27 does not affect the calculations performed in convolutional neural network 22 as such since said effects are given solely by the structure and the weights of the edges.

A convolutional layer 24 is, in particular, characterized in that the structure and the weights of the ingoing edges form a convolutional operation based on a specific number of kernels. In particular, the structure and the weights of the ingoing edges are chosen such that the values xₖ⁽ⁿ⁾ of nodes 29 of convolutional layer 24 are calculated as a convolution xₖ⁽ⁿ⁾=Kₖ*x⁽ⁿ⁻¹⁾ based on the values x⁽ⁿ⁻¹⁾ of nodes 28 of the preceding layer 23, the convolution * being defined in the two-dimensional case as

$${x}_{k}^{( n )} [ i , j ] = ( {K}_{k} * {x}^{( n - 1 )} ) [ i , j ] = {\sum }_{{i}^{′}} {\sum }_{{j}^{′}} {K}_{k} [ {i}^{′} , {j}^{′} ] \cdot {x}^{( n - 1 )} [ i - {i}^{′} , j - {j}^{′} ] .$$

Therein, the k-th kernel Kₖ is a d-dimensional matrix, in this exemplary embodiment, a two-dimensional matrix, which typically is small compared to the number of nodes 28 to 32, for example, a 3×3 matrix or a 5×5 matrix. In particular, this implies that the weights of the ingoing edges are not independent but are chosen such that they generate the above convolution equation. In the example of a kernel that forms a 3×3 matrix, there exist only nine independent weights (where each entry in the kernel matrix corresponds to an independent weight) regardless of the number of the nodes 28 to 32 in the corresponding layer 23 to 27. For a convolutional layer 24, the number of the nodes 29 in the convolutional layer 24 is, in particular, equivalent to the number of the nodes 28 in the preceding layer 23 multiplied by the number of the convolutional kernels.

If the nodes 28 in the preceding layer 23 are arranged as a d-dimensional matrix, using the plurality of kernels may be understood as the addition of a further dimension, which is also referred to as the depth dimension, such that the nodes 29 of the convolutional layer 24 are arranged as (d+1)-dimensional matrix. If the nodes 28 of the preceding layer 23 are already arranged as a (d+1)-dimensional matrix having a depth dimension, the use of a plurality of convolutional kernels may be understood as an expansion along the depth dimension, such that the nodes 29 of the convolutional layer 24 are likewise arranged as a (d+1)-dimensional matrix, the size of the (d+1)-dimensional matrix being greater in the depth dimension by the factor formed by the number of kernels than in the preceding layer 23.

The advantage of using convolutional layers 24 is that the spatially local correlation of the input data can be made use of by creating a local connectivity pattern between nodes of neighboring layers, in particular in that each node has connections only to a small section of the nodes of the preceding layer.

In the exemplary embodiment shown, input layer 23 comprises thirty-six nodes 28, which are arranged as a two-dimensional 6×6 matrix. Convolutional layer 24 comprises seventy-two nodes 29, which are arranged as two two-dimensional 6×6 matrices, each of the two matrices being the result of a convolution of the values of input layer 23 with a convolutional kernel. Equivalently thereto, nodes 29 of convolutional layer 24 may be understood as being arranged in a three-dimensional 6×6×2 matrix, the last-cited dimension being the depth dimension.

A pooling layer 25 is characterized in that the structure and the weights of the ingoing edges and the activation function of its nodes 30 define a pooling operation based on a nonlinear pooling function f. In the two-dimensional case, for example, the values x⁽ⁿ⁾ of the nodes 30 of the pooling layer 25 can be calculated based on the values x⁽ⁿ⁺¹⁾ of the nodes 29 of the preceding layer 24, as follows:

$${x}^{( n )} [ i , j ] = f ( {x}^{( n - 1 )} [ {id}_{1} , {jd}_{2} ] , … , {x}^{( n - 1 )} [ {id}_{1} + {d}_{1} - 1 , {jd}_{2} + {d}_{2} - 1 ] ) .$$

In other words, by using a pooling layer 25, it is possible to reduce the number of nodes 29, 30 by replacing a number of d₁×d₂ neighboring nodes 29 in the preceding layer 24 by a single node 30, which is calculated as a function of the values of the cited number of neighboring nodes 29. The pooling function f can be, in particular, a maximum function, an averaging, or the L2 norm. In particular, the weights of the ingoing edges can be specified for a pooling layer 25 and cannot be modified by training.

The advantage of using a pooling layer 25 is that the number of nodes 29, 30 and the number of parameters are reduced. This leads to a reduction in the computational load required within the convolutional neural network 22 and, consequently, to a control of the overfitting.

In the exemplary embodiment shown, pooling layer 25 is a max pooling layer in which just a single node replaces four neighboring nodes, the value of which is formed by the maximum of the values of the four neighboring nodes. The max pooling operation is applied to each d-dimensional matrix of the previous layer; in this exemplary embodiment, the max pooling operation is applied to each of the two two-dimensional matrices, as a result of which the number of nodes is reduced from seventy-two to eighteen.

A fully connected layer 26 is characterized in that a majority, in particular all, of the edges between the nodes 30 of the previous layer 25 and the nodes 31 of the fully connected layer 26 are present, wherein the weight of each of the edges can be adjusted individually. In this exemplary embodiment, the nodes 30 of the preceding layer 25 and of the fully connected layer 26 are represented both as two-dimensional matrices and, in addition, as non-related nodes (represented as a line of nodes, where the number of nodes has been reduced to provide better clarity of illustration). In this exemplary embodiment, the number of the nodes 31 in the fully connected layer 26 is equal to the number of the nodes 30 in the preceding layer 25. The number of the nodes 30, 31 may also be different in alternative forms of embodiment.

In this exemplary embodiment, the values of nodes 32 of output layer 27 are furthermore determined by applying the softmax function to the values of nodes 31 of the preceding layer 26. As a result of applying the softmax function, the sum of the values of all nodes 32 of output layer 27 is one, and all the values of all nodes 32 of the output layer are real numbers between 0 and 1. When convolutional neural network 22 is used for classifying input data, the values of the output layer 27, in particular, can be interpreted as the probability that the input data falls into one of the different classes.

A convolutional neural network 22 may also contain a ReLU layer (ReLU standing as an acronym for “rectified linear units”). In particular, the number of nodes and the structure of the nodes within a ReLU layer is equivalent to the number of nodes and the structure of the nodes in the preceding layer. In particular, the value of each node in the ReLU layer can be calculated by applying a rectifier function to the value of the corresponding node of the preceding layer. Examples of rectifier functions are f(x)=max(0,x), the hyperbolic tangent function, or the sigmoid function.

Convolutional neural networks 22 can be trained in particular based on the backpropagation algorithm. Regularization methods can be used in order to prevent overfitting, for example, dropout of individual nodes 28 to 32, stochastic pooling, use of artificial data, weight decay based on the L1 or L2 norm, or max norm constraints.

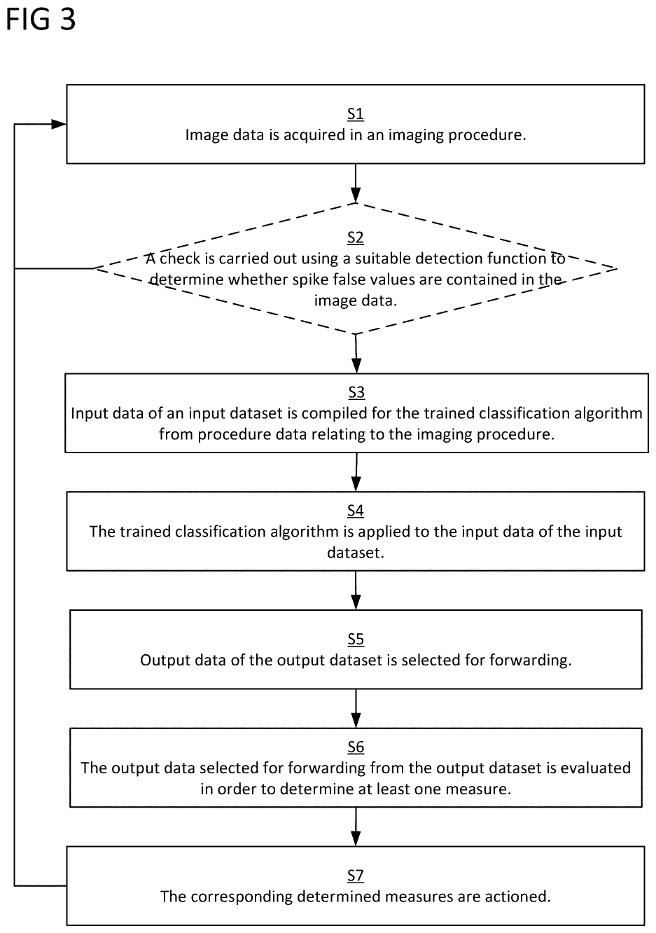

FIG. 3 shows a flowchart of an exemplary embodiment of the method according to the disclosure for operating a magnetic resonance facility on which image data is acquired in imaging procedures conducted on objects, in this case, patients. The magnetic resonance facility, in this case, comprises, as is generally known, a main magnet unit having a cylindrical patient receiving chamber into which the patient can be introduced by means of a motorized patient couch. The main magnet unit contains a superconducting main magnet for generating a main magnetic field. A radiofrequency coil array and a gradient coil array may be provided for surrounding the patient receiving chamber; local coils and the like may also be used as further radiofrequency coil arrays. The main magnet unit is arranged in a radiofrequency-shielded cabin. In this configuration, at least a part of a control facility performing the method and also controlling the rest of the operation of the magnetic resonance facility may also be located outside the shielded cabin.

Specifically, in a step S1, image data is acquired in an imaging procedure. In an optional step S2, a check can be carried out, for example, by means of a suitable detection function, to determine whether spike false values are contained in the image data, specifically in the measurement values in the k-space. If this is not the case, the data acquisition process is continued with the next imaging procedure. This function dedicated to identifying spike false values, i.e., local excessive increases in intensities, in particular, peaks and/or signal peaks, which do not describe the object, may also be integrated into the trained classification function that is still to be discussed in the following. In that event, step S1, if necessary also after a number of imaging procedures in step S1, would be followed immediately by step S3.

In step S3, input data of an input dataset is compiled for the trained classification algorithm from procedure data relating to the imaging procedure. In the present example, the input data of the input dataset comprises, in any case, the image data in the k-space and/or in a hybrid space and/or in the image space as radiofrequency signal data. This radiofrequency signal data, which relates, of course, to received radiofrequency signals that are also responsible for the corresponding spike, may also comprise sensor data acquired by at least one further radiofrequency sensor or breath sensor not used for the imaging. Further radiofrequency sensors of said type may, for example, comprise pickup coils that can be provided at different points in the shielded cabin and/or a breath sensor.

In the course of the compilation, two new dimensions are added to the image data in the present case, i.e., firstly, the coil channels containing the spatial information in which the respective signals were acquired, but secondly also the time intervals in which certain k-space sections, for example, k-space lines, were acquired specifically the respective shot.

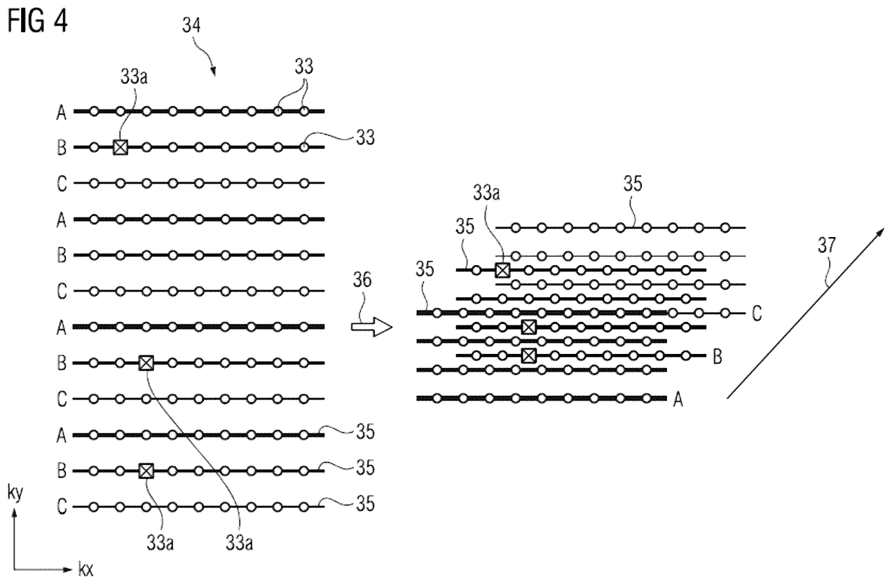

This is explained in more detail with reference to FIG. 4. This shows schematically, on the left-hand side, a k-space that is sampled at various measurement points 33 and has the directions kx and ky. In this case, k-space lines 35, labeled here with A, B, C, were acquired in three shots as k-space sections 34. This means that the k-space lines 35 labeled with A were acquired in a first time interval following a common excitation pulse, the k-space lines 35 labeled with B were acquired in a second time interval following a common excitation pulse, and the k-space lines 35 labeled with C were acquired in a third time interval following a common excitation pulse. In the present case, some k-space points 33a are highlighted specifically by way of example since spike false values are present at these k-space points 33a. As can be seen, all these k-space points 33a lie on k-space lines 35 that were acquired in the second shot B. This means that a temporal correlation is present. In order to make this recognizable also for the subsequently applied trained classification function, these k-space sections 34, specifically the k-space lines 35, are sorted afresh or concatenated during the compilation of the input dataset according to the arrow 36, and moreover along a new dimension “shot.” It can now clearly be seen that all of the k-space points 33a are to be found in the middle set of k-space lines 35 associated with shot B. This new dimension of shots A, B, C is marked by the arrow 37 in FIG. 4.

In step S3, returning to FIG. 3, supplementary information is also selected from the procedure data and is to be added to the input dataset. In the present example, said supplementary information comprises coil information describing coils used for the imaging, orientation information describing the orientation of measured volumes and layers hereof, and gradient information describing the gradient pulses played out during the imaging procedure. The gradient information yields, in particular, a main activity direction of the gradients. Further, the supplementary information may also comprise a temperature measurement value of at least one temperature sensor of the magnetic resonance facility and a door sensor signal indicating the closure state of a door of the shielded cabin.

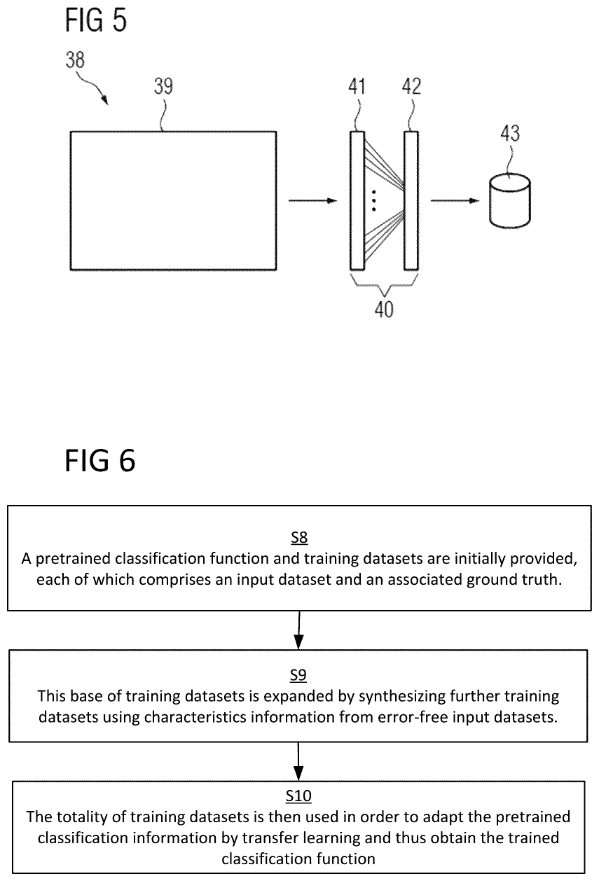

In a step S4, following the compilation of the input dataset, the trained classification algorithm is applied to the input data of the input dataset. The trained classification algorithm comprises a convolutional neural network 22, in the present case, by way of example, a ResNet-18, the general structure of which is explained in more detail in FIG. 5. Accordingly, the trained classification function 38 comprises a convolutional base 39, which, as is generally known, is constructed mainly from convolutional layers 24 and pooling layers 25. In this case, “skip connections” may be present between different convolutional blocks. The convolutional base 39 is followed by a classifier 40, which, in the present case, by way of example, comprises a first fully connected layer 41 containing 512 nodes and a second fully connected layer 42 containing a number of nodes corresponding to the number of causes for spike false values that can be distinguished by the classification function 38, possibly increased by one. The increase by one is useful when the trained classification function 38 is embodied also for detecting the presence of false values, such that the additional node or entry in the vector of probability values forming the output dataset 43 can indicate that no interference has been found. The, possibly further, entries, i.e., probability values, in the output dataset 43 then relate to the probabilities for the presence of different causes for the false values in the image data, for example, “loose gradient cable,” “voltage surge in gradient coil,” “radiofrequency interference sources outside the shielded cabin,” “radiofrequency interference sources inside the shielded cabin,” “metallic object in the patient receiving chamber,” etc. The output dataset 43, in particular, assigned to entries, may also contain further information, in particular localization information, describing the location of the cause, in the case of defects or loose cables, for example, the corresponding actual cable. However, these localizations may also be described by way of separate entries in the vector. Localization information can be determined by the classification function 38 using the supplementary information, for example. The corresponding results can then be stored, for example, in further entries in the fully connected layer 42.

In a step S5, output data of the output dataset is selected for forwarding. For example, a uniqueness criterion can be evaluated here, which decides whether a uniquely clear cause (or, if applicable, the declaration “no interference”) is to be forwarded, i.e., the result is sufficiently unique, or whether a number of potential causes, in particular with associated probabilities, are to be forwarded. In this process, the uniqueness criterion can, for example, conduct threshold value comparisons, in which case, for example, threshold values can be specified which must exceed the probability for forwarding (for example, 25 or 30 percent) and/or a check is carried out in respect of the uniqueness to determine whether one probability value is greater than 50 percent and/or by a specific percentage higher than the next lower probability value.

In a step S6, the output data selected to be forwarded from the output dataset 43 is evaluated in order to determine at least one measure. Possible measures in the present case comprise making an entry into an error memory, outputting an alert containing the outputted output data to a user or related to said output data, sending a message to a maintenance service that accordingly contains the outputted output data or can be related to said output data, and selecting and applying a correction algorithm, if necessary using the output data, for the image data. A message to a maintenance service can, for example, contain alerts indicating which components of the magnetic resonance facility need to be checked. The output of an alert to the operating personnel can be, for example, of the style “Interfering signals detected. Please check whether power supply units or defective fluorescent tubes are present in the scanner room.” and be output optically and/or acoustically. The correction algorithm may be understood as a false value correction measure and, in reality, may be, for example, an image correction function, in particular of such type that makes use of a neural network in order to eliminate random interferences or performs actual correction measures, for example removing or replacing certain data points in k-space lines 35.

The corresponding determined measures are actioned in step S7, after which a return to step S1 can be made.

FIG. 6 shows steps for providing the trained classification function 38. In this case, in a step S8, a pretrained classification function as well as training datasets are initially provided, each of which comprises an input dataset and an associated ground truth, in particular an output dataset 43, i.e. they are annotated. This base of training datasets is expanded further in a step S9 by synthesizing further training datasets using characteristics information from error-free input datasets. The totality of training datasets is then used in a step S10 in order to adapt the pretrained classification information by transfer learning and thus obtain the trained classification function 38. It is conceivable, in particular in this case, that in exemplary embodiments, the convolutional base 39 remains unchanged, at least to some extent, and only the classifier 40 is adapted, i.e., effort is directed to the features already identifiable in the pretrained classification information.

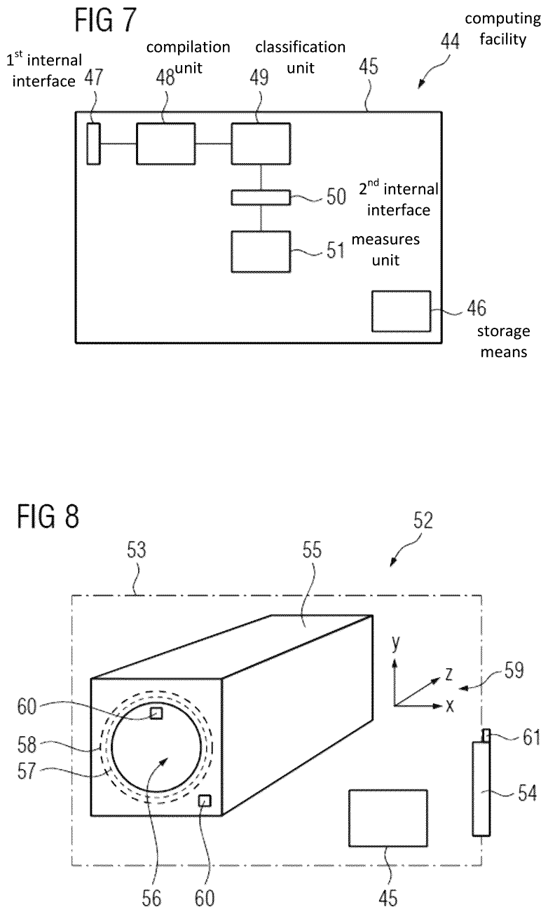

FIG. 7 shows the functional structure of a computing facility 44 according to the disclosure, which in the present case is embodied as a control facility 45 of a magnetic resonance facility. In addition to a storage means 46, in which, for example, the trained classification function 38 may also be stored alongside various data, the computing facility 44 further comprises various functional units for performing steps of the method according to the disclosure, as well as in the present case internal, interfaces. Procedure data relating to the imaging procedure is received via a first internal interface 47, for example, from a sequence unit that controls the acquisition operation. The sequence unit (not shown here in more detail) can, for example, control the imaging procedure in step S1. The input dataset is compiled according to step S3 in a compilation unit 48. The classification algorithm is applied according to step S4 in a classification unit 49. Output data to be forwarded from the output dataset 43 according to step S5 can then also be selected already in the classification unit 49. This output data to be output or forwarded from the output dataset 43 passes via a second internal interface 50 to reach a measures unit 51 for the purpose of performing steps S6 and S7.

Finally, FIG. 8 shows a schematic diagram of a magnetic resonance facility 52, which in the present case comprises a main magnet unit 55 disposed in a shielded cabin 53 with a door 54 and having a main magnet (not shown in more detail) generating the main magnetic field of the magnetic resonance facility 52. The main magnet unit 55 defines a cylindrical patient receiving chamber 56 into which a patient can be introduced by means of a motorized patient couch (not shown here in more detail) for the purpose of performing an imaging procedure. A radiofrequency coil array 57 (whole-body coil array) and a gradient coil array 58 comprising gradient coils for the three main directions of the magnetic resonance facility 52 can be arranged surrounding the patient receiving chamber 56. A corresponding coordinate system 59 is indicated.

The operation of the magnetic resonance facility 52 is controlled by means of the control facility 45, part(s) of which may also be arranged outside the shielded cabin 53. Furthermore, said control facility 45 also receives sensor data from further radiofrequency sensors 60, as indicated at two points by way of example, and signals from a door opening sensor 61, which is assigned to the door 54.

Although the disclosure has been illustrated and described in more detail on the basis of the preferred exemplary embodiment, the disclosure is not limited by the disclosed examples and other variations can be derived herefrom by the person skilled in the art without leaving the scope of protection of the disclosure.

Independent of the grammatical term usage, individuals with male, female or other gender identities are included within the term.

1. A computer-implemented method for operating a magnetic resonance facility to determine at least one potential cause of a false value in image data of an imaging procedure, comprising:
compiling an input dataset that is to be analyzed and comprises radiofrequency signal data acquired during the imaging procedure;
applying a trained artificial intelligence classification function to the input dataset to determine an output dataset that describes potential causes of the false value; and
outputting at least a portion of the output data of the output dataset.

2. The method as claimed in claim 1, wherein the radiofrequency signal data comprises at least a portion of the image data of the imaging procedure in k-space and/or in a hybrid space and/or in image space.

3. The method as claimed in claim 2, wherein during acquisition of multiple k-space sections following a common excitation pulse in one shot, the k-space sections are assigned to the respective shot as an additional dimension of the radiofrequency signal data of the input dataset, and/or that, as a further dimension of the radiofrequency signal data of the input dataset, an assignment to a coil channel in which the signal data was acquired is used.

4. The method as claimed in claim 1, wherein the radiofrequency signal data comprises sensor data acquired by at least one further radiofrequency sensor of the magnetic resonance facility that is not used for the imaging.

5. The method as claimed in claim 4, wherein the at least one further radiofrequency sensor comprises a pickup coil and/or a breath sensor.

6. The method as claimed in claim 1, wherein the input dataset comprises at least one item of supplementary information about the imaging procedure in addition to the radiofrequency signal data.

7. The method as claimed in claim 6, wherein the supplementary information is selected from a group consisting of:
coil information describing coils used for the imaging;
orientation information describing an orientation of measured volumes and/or gradient information describing gradient pulses played out during the imaging procedure;
at least one temperature measurement value of a temperature sensor of the magnetic resonance facility; and
a door sensor signal indicating a closure state of a door of a shielded cabin of the magnetic resonance facility.

8. The method as claimed in claim 7, wherein the trained classification function, by using the supplementary information, determines, in relation to at least one cause, localization information describing a location of the cause as part of the output dataset.

9. The method as claimed in claim 1, wherein the trained classification function comprises a ResNet, in particular a ResNet-18, and/or an AlexNet and/or a SqueezeNet, as a neural network.

10. The method as claimed in claim 1, wherein at least one measure is determined and actioned based on the outputted output data.

11. The method as claimed in claim 10, wherein the at least one measure is selected from a group consisting of:
storing an entry in an error memory;
outputting an alert to a user;
sending a message to a maintenance service; and
applying a correction algorithm to the image data.

12. The method as claimed in claim 1, wherein in order to provide the trained classification function, a pretrained classification function is provided and trained using transfer learning based on training datasets, wherein each training dataset comprises an input dataset and an associated ground truth.

13. The method as claimed in claim 12, wherein at least some of the input datasets of the training datasets are determined from base datasets free of false values using characteristics information assigned to causes.

14. A non-transitory electronically readable data medium having stored thereon a computer program having program means such that when the computer program is executed on a computing facility, the computing facility performs the steps of the method as claimed in claim 1.

15. A computing facility for determining at least one potential cause for a false value in image data of at least one imaging procedure, comprises:
a first interface operable to receive procedure data describing the imaging procedure and comprising at least radiofrequency signal data acquired during the imaging procedure;
a compilation unit operable to compile, from the procedure data, an input dataset that is to be analyzed and contains at least a portion of the radiofrequency signal data;
a classification unit operable to apply a trained artificial intelligence classification function to the input dataset to determine an output dataset that describes potential causes of the false value; and
a second interface operable to output at least a portion of the output data of the output dataset.
